(19) United States
(12) Patent Application Publication
(10) Pub. No.: US 2021/0241979 A1
(43) Pub. Date: Aug. 5, 2021

(54) WIDE SPECTRUM DETECTOR AND PREPARATION METHOD

(71) Applicant: TIANJIN UNIVERSITY, Tianjin (CN)

(72) Inventors: Yating ZHANG, Tianjin (CN); Yifan LI, Tianjin (CN); Tengteng LI, Tianjin (CN); Qingyan LI, Tianjin (CN); Jianquan YAO, Tianjin (CN)

(73) Assignee: TIANJIN UNIVERSITY, Tianjin (CN)

(21) Appl. No.: 17/147,612

(22) Filed: Jan. 13, 2021

(30) Foreign Application Priority Data
Jan. 14, 2020 (CN) 202010038865.2

(51) Int. Cl. H01G 9/20; H01L 51/42; H01L 51/44

(52) U.S. Cl. CPC H01G 9/20; H01L 51/441; H01L 51/4253

(57) ABSTRACT

A wide spectrum detector and a preparation method. The detector includes: a substrate and at least one detection unit, wherein the at least one detection unit is provided on the substrate and the at least one detection unit includes: two metal electrodes and a perovskite material layer, wherein the perovskite material layer is in ohmic contact with the two metal electrodes.

This application claims the benefit of priority of Chinese Patent Application No. 202010038865.2 filed on Jan. 14, 2020, which is incorporated herein in its entirety by reference.

### TECHNICAL FIELD

The present disclosure relates to the field of terahertz detection technology, in particular to a wide spectrum detector and a preparation method.

### BACKGROUND

At present, there are relatively mature detector technologies commercially available, such as silicon (Si) detectors, indium gallium arsenic (InGaAs) detectors, germanium (Ge) detectors, etc. Example response bands and responsivities of the detectors listed above can be found in Table 1.

TABLE 1

| Type | Response band (nm) | Responsivity (A/W) |
|---|---|---|
| D Si 200 | 200-1100 | 0.52 |
| D InGaAs 1650 | 800-1700 | 0.85 |
| Ge | 400-2000 | 0.85 |

### SUMMARY

However, a coverage band of each detector mentioned above is difficult to cover the ultraviolet to terahertz band, and the responsivity is 1 A/W. At the same time, each detector mentioned above is difficult to be made flexible and wearable, so it is difficult to meet various requirements in practical applications.

The present disclosure provides a wide spectrum detector and a preparation method to realize technical effects of a wide spectrum detection and an improved responsivity.

In an aspect, an embodiment of the present disclosure provides a wide spectrum detector, which includes: a substrate and at least one detection unit; wherein,

the at least one detection unit is provided on the substrate;

the at least one detection unit comprises two metal electrodes and a perovskite material layer; and

the perovskite material layer is in ohmic contact with the two metal electrodes.

In an embodiment, the at least one detection unit comprises one detection unit, wherein the one detection unit comprises:

a first metal electrode provided on the substrate;

the perovskite material layer provided on the first metal electrode; and

a second metal electrode provided on the perovskite material layer.

In an embodiment, the substrate has conductivity and serves as the first metal electrode;

the perovskite material layer is provided on the substrate;

the second metal electrode is provided on the perovskite material layer; and

the two metal electrodes comprise the substrate and the second metal electrode.

In an embodiment, a size of the first metal electrode is smaller than that of the substrate; a size of the perovskite material layer is smaller than or equal to that of the first metal electrode; and a size of the second metal electrode is smaller than that of the perovskite material layer.

In an embodiment, the first metal electrode and the second metal electrode are different kinds of metal electrodes or the same kind of metal electrodes.

In an embodiment, the at least one detection unit comprises one detection unit, wherein the one detection unit comprises:

a perovskite material layer being spin-coated on the substrate; and

two metal electrodes provided on the perovskite material layer, wherein a distance between the two metal electrodes is within a preset range, so as to form a channel between the two metal electrodes.

In an embodiment, a size of the perovskite material layer is smaller than or equal to that of the substrate, and a sum of sizes of the two metal electrodes is smaller than that of the perovskite material layer.

In an embodiment, a thickness of the perovskite material layer is between 100 nm and 1 μm.

In an embodiment, the at least one detection unit comprises at least two detection units, and the at least two detection units are arranged in a plane or in a line.

In an aspect, an embodiment of the present disclosure provides a method for preparing a wide spectrum detector, the method including:

preparing a first metal electrode on a substrate;

preparing a perovskite material layer on the first metal electrode; and

preparing a second metal electrode on a side of the perovskite material layer away from the first metal electrode.

In an embodiment, before preparing a second metal electrode on a side of the perovskite material layer away from the first metal electrode, the method further comprises subjecting the first metal electrode prepared on the substrate to ultraviolet ozone treatment, so as to improve adhesivity between the perovskite material layer and the first metal electrode.

In an embodiment, preparing the perovskite material on the first metal electrode comprises using a spin-coating method or an evaporation method to prepare the perovskite material on the first metal electrode.

In an aspect, an embodiment of the present disclosure provides a method for preparing a wide spectrum detector, the method including:

preparing a perovskite material layer on a substrate; and

preparing two metal electrodes on the perovskite material layer,

wherein a distance between the two metal electrodes in the horizontal direction is within a preset range.

In a technical solution of an embodiment of the present disclosure, by providing at least one detection unit on a substrate, wherein the at least one detection unit includes two metal electrodes and a perovskite material layer, and the perovskite material layer is in ohmic contact with the two metal electrodes, a technical problem of a detector made of silicon, indium gallium arsenide, or germanium in the art, such as small coverage, low responsiveness, and/or difficulty to meet the needs of various aspects, can be solved. The technical effects that an improved coverage range from ultraviolet to terahertz band of the detector, and a high responsivity can be realized, which can improve an application range.

### BRIEF DESCRIPTION OF THE DRAWINGS

In order to describe the technical solutions of the exemplary embodiments of the present disclosure more clearly, the accompanying drawings used in describing the embodiments are briefly introduced in the following. Obviously, the drawings described are only the drawings of a part of the embodiments to be described in the present disclosure, rather than all drawings. For those of ordinary skill in the art, other drawings may be obtained from these drawings without creative work.

FIG. 1 is a schematic structural diagram of a wide spectrum detector provided by an embodiment of the present disclosure;

FIG. 2 is a schematic cross-sectional view taken along A-A′ in FIG. 1;

FIG. 3 is a schematic structural diagram of a wide spectrum detector provided by an embodiment of the present disclosure;

FIG. 4 is a schematic structural diagram of a wide spectrum detector provided by an embodiment of the present disclosure;

FIG. 5 is an I-V characteristic graph of a wide spectrum detector provided by an embodiment of the present disclosure;

FIG. 6a shows a response diagram of an optical switch under the condition of 405 nm illumination;

FIG. 6b shows a response diagram of an optical switch under the condition of 532 nm illumination;

FIG. 6c shows a response diagram of an optical switch under the condition of 1064 nm illumination;

FIG. 6d shows a response diagram of an optical switch under the condition of 10.6 μm illumination;

FIG. 6e shows a response diagram of an optical switch under the condition of 2.52 THz illumination;

FIG. 7 is a flow chart of preparing a wide spectrum detector provided by an embodiment of the present disclosure;

FIG. 8 is another flow chart for preparing a wide spectrum detector provided by an embodiment of the present disclosure.

### DETAILED DESCRIPTION

The present disclosure will be further described in detail below with reference to the drawings and embodiments. It can be understood that the specific embodiments described here are only used to explain the present disclosure, but not to limit the present disclosure. In addition, it should be noted that, for ease of description, the drawings only show a part but not all of the structure related to the present disclosure.

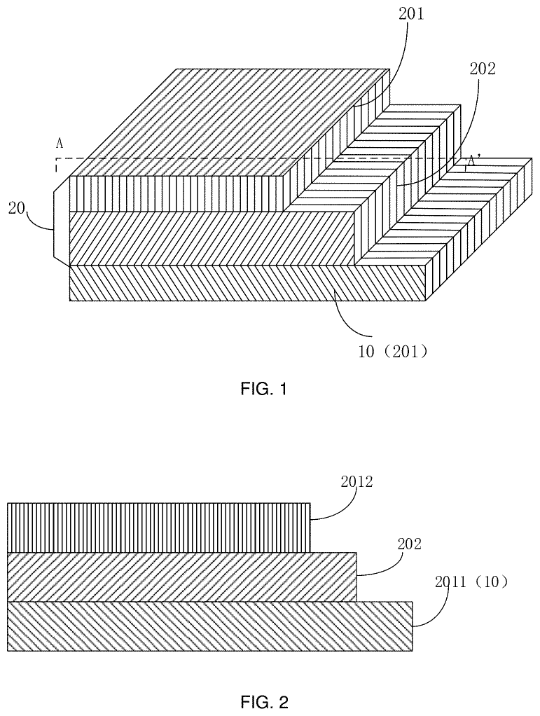

FIG. 1 is a schematic structural diagram of a wide spectrum detector according to an embodiment of the present disclosure. As shown in FIG. 1, the detector includes a substrate 10 and at least one detection unit 20. In an embodiment, at least one detection unit 20 is provided on the substrate 10. At least one detection unit 20 includes two metal electrodes 201 and a perovskite material layer 202, and the perovskite material layer 202 is in ohmic contact with the metal electrode 201.

In an embodiment, the number of at least one detection unit 20 can be set by a user according to actual conditions. Optionally, the number of the at least one detection unit 20 is two, tens, hundreds, or thousands, etc. When the number of at least one detection unit 20 is more than one, the at least one detection unit 20 may be arranged in a plane or in a line. A planar arrangement can be understood as a dot matrix arrangement. Optionally, the number of at least one detection unit 20 is 16, such as a 4×4 dot matrix arrangement. A line arrangement can be understood as a linear arrangement of multiple detection units 20. When the number of the at least one detection unit 20 is more than one, a detection efficiency of the detector can be improved, and it can also be used for imaging.

The two metal electrodes 201 can be the same kind of metal electrode 201 or different kinds of metal electrode 201, and it only needs to satisfy that the metal electrodes 201 are inert electrodes. Optionally, the metal electrode 201 can be made of gold (Au), titanium (Ti) and/or other materials. Perovskite is abbreviated as ABO₃, wherein A represents an organic molecule, mainly including CH₃NH₃+, or NH₂CHNH₂+; B is usually a divalent lead ion and/or tin ion; and O is a halogen element (CI, Br, I, etc.). Perovskite materials mainly include inorganic perovskite (CsPbBr₃) and inorganic-organic hybrid perovskite (CH₃NH₃PbI₃). In this embodiment, the organic hybrid perovskite material is mainly used. It should be noted that the above only lists one of the perovskite materials, and the user can select the type of perovskite materials to be prepared according to actual needs. However, if the structure and the implementation of this embodiment are adopted, they are all within the protection scope of this embodiment. The perovskite material is prepared in advance and can be prepared on the metal electrode by spin coating or evaporation. After the perovskite material is prepared on the metal electrode 201, the perovskite material layer 202 is obtained.

It should be noted that because the perovskite material is prepared on the metal electrode, the detector obtained can realize a wide spectrum detection, that is, when the structure mentioned above is adopted, the detection range of the detector can cover from ultraviolet to terahertz band, and then a wide spectrum detection is realized.

Specifically, a preset preparation method, optionally, spin coating, evaporation, sputtering, etc., is adopted to prepare the at least one detection unit 20 on the substrate 10 to obtain a wide spectrum detector.

Optionally, the at least one detection unit includes one detection unit 20. That is, the number of the detection unit is one. In this embodiment, the number of detection unit 20 as one is taken as an example for introduction. The detection unit 20 includes a first metal electrode 2011, a perovskite material layer 202, and a second metal electrode 2012. The first metal electrode 2011 is provided on the substrate 10, the perovskite material layer 202 is provided on the first metal electrode 2011, and the second metal electrode 2012 is provided on the perovskite material layer 202. FIG. 2 is a cross-sectional view of such a detection unit. FIG. 2 is a cross-sectional view taken along A-A′ in FIG. 1.

In an embodiment, the at least one detection unit 20 has a vertical structure, and the vertical structure may be understood as a laminated structure in a vertical direction, see FIG. 1. Evaporation may be used to evaporate gold (Au) on the substrate 10 to obtain a first metal electrode of the two metal electrodes in the at least one detection unit 20. Of course, the material selected for evaporation may be one or more other materials, and the user may select according to actual needs. After the first metal electrode is obtained, the perovskite material prepared in advance may be spin coated on the first metal electrode, so as to obtain the perovskite material layer 202.

In an embodiment, during the process when the perovskite material is spin-coated on the first metal electrode, a rotation speed used during spin-coating may be 3000-8000 rpm, optionally 3000 rpm. In order to obtain the perovskite material layer 202, the spin-coated perovskite material may be annealed, and an annealing temperature may be between 60° C. and 150° C. In order to obtain the at least one detection unit 20, a second metal electrode of the two metal electrodes is provided on the perovskite material layer 202, e.g., by evaporation.

It should be noted that the first metal electrode and the second metal electrode can be made of the same material or different materials. Optionally, the first metal electrode is made of Au material, and the second metal electrode is made of Ti material. The materials adopted for the first metal electrode and/or the second metal electrode can be, e.g., ITO, Au, Al, Ti, etc.

Optionally, if the substrate has conductivity, the substrate may be used as the first metal electrode, the perovskite material layer is prepared on the substrate, and the second metal electrode is prepared on the perovskite material layer. A specific structure of such is shown in FIG. 1. That is to say, in the actual application process, if the substrate has conductivity, the substrate may be directly used as the metal electrode, that is, the first metal electrode.

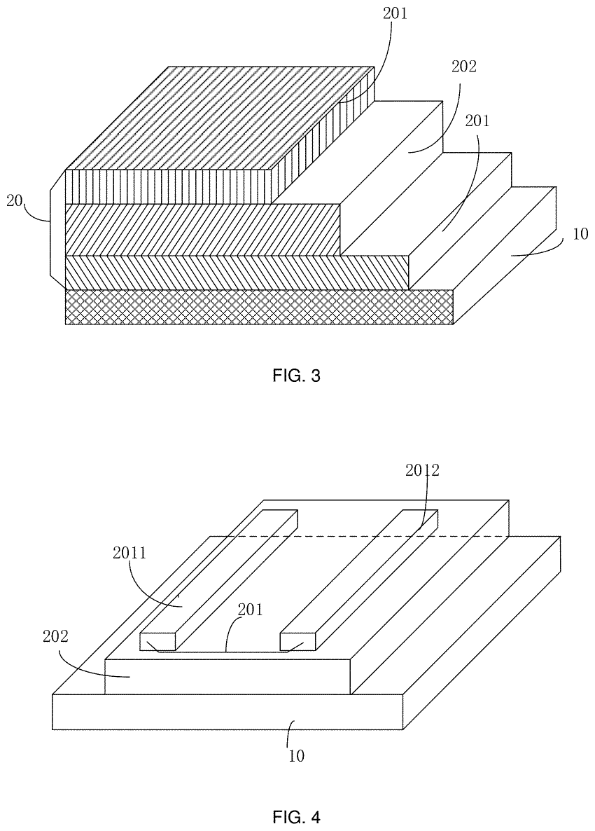

In an embodiment, when the detection unit has a vertical structure, a size of the first metal electrode (e.g., first metal electrode 2011) is smaller than that of the substrate 10, a size of the perovskite material layer 202 is smaller than that of the first metal electrode, and a size of the second metal electrode (e.g., second metal electrode 2012) is smaller than that of the perovskite material layer 202. See, e.g., FIG. 3. A reason for such arrangement is to fully consider the technical effect that the circuit can be effectively connected without losing the effective layer.

It should be noted that the detection unit 20 may be not only a vertical structure, but also a horizontal structure. See, e.g., FIG. 4. Optionally, the at least one detection unit 20 includes the perovskite material spin-coated on the substrate 10 to obtain a perovskite material layer 202. Two metal electrodes 201 are provided on the perovskite material layer 202, and a distance between the two metal electrodes 201 is within a preset range, so that a channel is formed between the two metal electrodes 201.

Referring to FIG. 4, the perovskite material layer 202 is provided on the substrate, and, in an embodiment, a first metal electrode 2011 (of the metal electrodes 201) and a second metal electrode 2012 (of the metal electrodes 201) are evaporated on the perovskite material layer 202. At the same time, after the two metal electrodes 201 are evaporated on the perovskite material layer 202, a sum of sizes of the two metal electrodes 201 is smaller than the size of the perovskite material layer 202. That is, the sum of sizes of the two metal electrodes 201 is smaller than the size of the perovskite material layer 202, and there is a certain distance between the two metal electrodes, serving as a channel. An advantage of such arrangement is that it is convenient for hot carriers generated by the perovskite material to be transported between the two electrodes, and the conductivity effectiveness is improved.

On the basis of the above technical solution, it should be noted that a thickness of the perovskite material layer 202 is generally between 100 nm and 1 μm. An advantage of such arrangement is that it can beneficially generate more effective hot carriers, thereby increasing the absorbance.

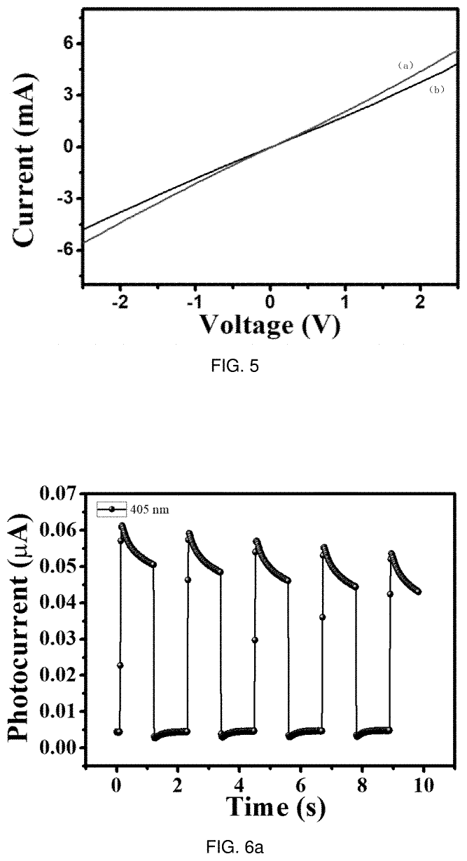

On the basis of the above technical solution, the perovskite material layer should form a good ohmic contact with the metal electrodes. An advantage of such arrangement is show in FIG. 5. FIG. 5 shows I-V characteristic curves of the detector with and without illumination. In the graph, curve (a) represents the I-V characteristic curve of the detector without illumination; and curve (b) represents the I-V characteristic curve of the detector with illumination. It can be seen from FIG. 5 that in the process of gradually increasing an applied voltage value, a rate of change of curve (b) is greater than that of curve (a), indicating that under the condition of the same voltage, the current generated with illumination is larger than the current generated without illumination. That is, photothermal carriers are generated under the illumination condition, and a photoelectric detection is realized.

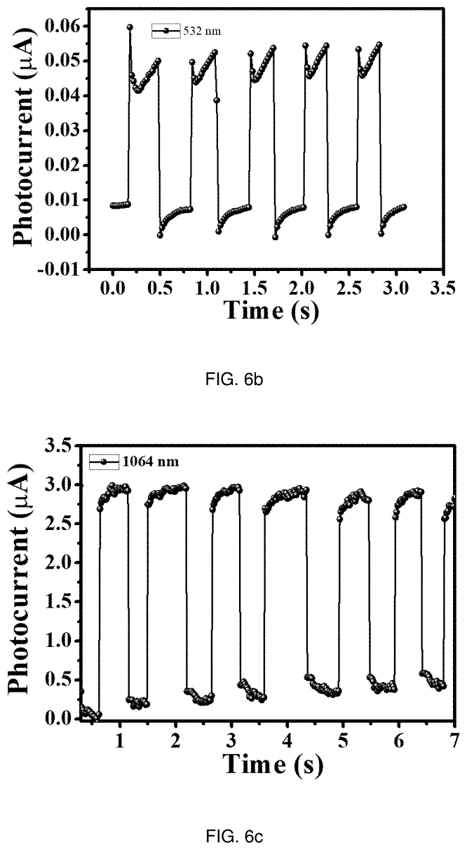

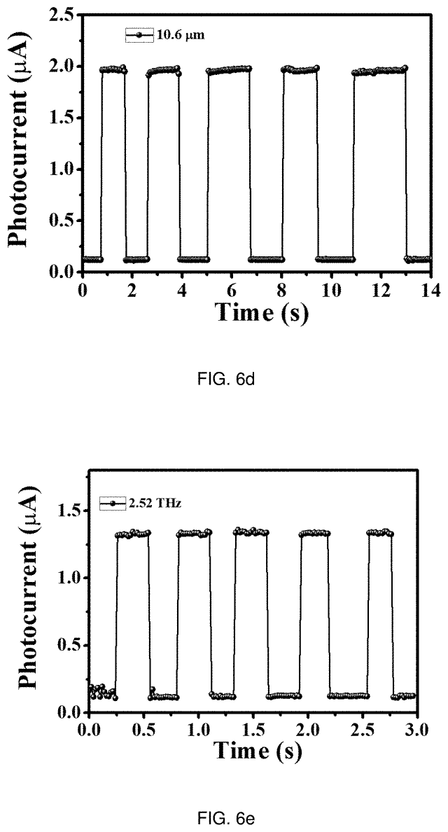

In order to further verify whether the device achieves a wide spectrum detection, a series of experiments were carried out, and effects thereof are shown in FIGS. 6a to 6e. FIGS. 6a to 6e respectively show corresponding optical switch response diagrams of this type of device under the illumination conditions of 405 nm, 532 nm, 1064 nm, 10.6 μm (30 THz), and 118 μm (2.52 THz). As shown in these drawings, each current value of the detector changes significantly under condition of illumination of different wavelengths, that is, each exhibits obvious optical switch characteristics. In other words, under the condition where the illumination is on, the current value changes significantly within a certain period of time, and under the condition where the illumination is off, the current drops rapidly. On the basis of experimental results shown in FIGS. 6a to 6e, it can be seen that the detector prepared based on the preparation method above can realize an ultra-wide spectrum detection, that is, the photoelectric response characteristics from ultraviolet to terahertz band is realized, and the response is sensitive and the optical switch characteristics is obvious, which can be widely used as an ultra-wide spectrum detector.

In a technical solution of the embodiment of the present disclosure, by providing at least one detection unit on a substrate, wherein the at least one detection unit includes two metal electrodes and a perovskite material layer, and the perovskite material layer is in ohmic contact with the two metal electrodes, a technical problem of a detector made of silicon, indium gallium arsenide, or germanium in the art, such as small coverage, low responsiveness, and/or difficulty to meet the needs of various aspects, is solved. Technical effects such an improved coverage range from ultraviolet to terahertz band of the detector, and/or a high responsivity, can be realized, which can improve an application range.

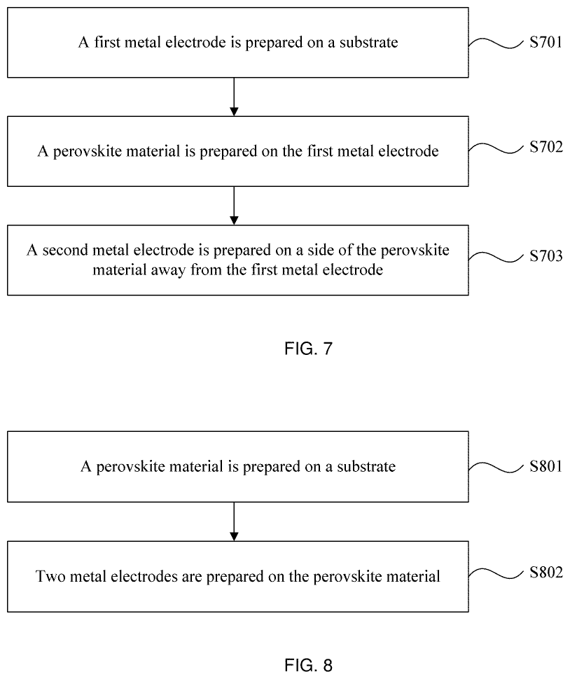

FIG. 7 is a flow chart of a process for preparing a wide spectrum detector according to an embodiment of the present disclosure. As shown in FIG. 7, a preparation method includes:

S701. A first metal electrode is prepared on a substrate.

In an embodiment, the substrate may be silicon dioxide or one or more other materials. If the substrate has conductivity, the substrate may be used as a first metal electrode.

If the substrate does not have conductivity, a first metal electrode may be prepared on the substrate. Gold (Au) material may be used to prepare the first metal electrode. Specifically, an evaporation method may be used to evaporate gold (Au) material on the substrate to obtain the first metal electrode.

It should be noted that other methods may be used to prepare the first metal electrode on the substrate, optionally, sputtering. Of course, users can also select corresponding other metal materials and preparation methods according to actual needs to obtain the first metal electrode.

S702. A perovskite material is prepared on the first metal electrode.

After the first metal electrode is obtained, in order to obtain a wide spectrum detector, perovskite material may be prepared on the first metal electrode to obtain a perovskite material layer.

It should be noted that the perovskite material is prepared in advance. Optionally, the perovskite material prepared in advance is a material such as methyl lead iodide ammonia and so on.

In order to improve adhesivity between the perovskite material layer and the first metal electrode, before the perovskite material is prepared on the first metal electrode, the substrate and/or the first metal electrode should be treated with an ultraviolet ozone treatment, so as to improve the adhesivity between the first metal electrode and the perovskite material, thereby achieving a good ohmic contact between the perovskite material layer and the first metal electrode, and improving performance of the detector.

In an embodiment, a spin-coating method may be used to prepare the perovskite material on the first metal electrode, and a rotation speed of the spin-coating may be any rotation speed from 3000 rpm to 8000 rpm, desirably 3000 rpm.

S703. A second metal electrode is prepared on a side of the perovskite material away from the first metal electrode.

After the perovskite material layer is obtained, a second metal electrode may be prepared on the perovskite material layer. In other words, there is a perovskite material layer existing between the first metal electrode and the second metal electrode. Of course, the second metal electrode may also be prepared by an evaporation method, which is not repeated here.

It should be noted that, from a substrate layer to the second metal electrode layer, a size of each layer is gradually decreasing. The purpose of this is to help achieve the technical effect that the circuit can be effectively connected without losing the effective layer.

In a technical solution of an embodiment of the present disclosure, by providing at least one detection unit on a substrate, wherein the at least one detection unit includes two metal electrodes and a perovskite material layer, and the perovskite material layer is in ohmic contact with the two metal electrodes, a technical problem of a detector made of silicon, indium gallium arsenide, or germanium in the art, such as small coverage, low responsiveness, and/or difficulty to meet the needs of various aspects, can be solved. The technical effects that an improved coverage range from ultraviolet to terahertz band of the detector, and/or a high responsivity, can be realized, which can improve an application range.

FIG. 8 is a flow chart of another process for preparing a wide spectrum detector according to an embodiment of the present disclosure. As shown in FIG. 8, a preparation method includes:

S801. A perovskite material is prepared on a substrate.

It should be noted that the detection unit in the method described with respect to FIG. 7 can adopt a vertical structure. This embodiment involves preparation of a horizontal structure of the detection unit as an example.

A spin-coating method may be used to spin coat the perovskite material on the substrate, and subject the substrate spin-coated to annealing treatment to obtain the perovskite material layer. In an embodiment, a rotation speed during spin-coating the perovskite material is 3000 rpm, and the coating time is 40 s, and then the spin-coated perovskite material is annealed at 100° C. to obtain the perovskite material layer.

Of course, in order to improve the adhesivity between the substrate and the perovskite material layer, the substrate may be subjected to ultraviolet ozone treatment before the perovskite material layer is prepared on the substrate.

S802. Two metal electrodes are prepared on the perovskite material.

An evaporation method may be used to evaporate two metal electrodes on the perovskite material layer. The two metal electrodes may be the same or different, and users can set them according to actual needs.

It should be noted that a sum of size of the two metal electrodes is smaller than the size of the perovskite material layer, and there is a certain distance between the metal electrodes, serving as a channel.

In a technical solution of an embodiment of the present disclosure, by providing at least one detection unit on a substrate, wherein the at least one detection unit includes two metal electrodes and a perovskite material layer, and the perovskite material layer is in ohmic contact with the two metal electrodes, a technical problem of a detector made of silicon, indium gallium arsenide, or germanium in the art, such as small coverage, low responsiveness, and/or difficulty to meet the needs of various aspects, can be solved. Technical effects of an improved coverage range from ultraviolet to terahertz band of the detector, and/or a high responsivity, can be realized, which can improve an application range.

Note that the above are only embodiments of the present disclosure and the technical principles applied. Those skilled in the art will understand that the present disclosure is not limited to the specific embodiments described herein, and various obvious changes, readjustments and substitutions can be made to those skilled in the art without departing from the protection scope of the present disclosure. Therefore, although the present disclosure has been described in more detail through above embodiments, the present disclosure is not limited to the above embodiments, and can also include more other equivalent embodiments without departing from the concept of the present disclosure. The scope of the present disclosure is determined by the scope of appended claims.

What is claimed is:

1. A wide spectrum detector, comprising:
a substrate; and
at least one detection unit provided on the substrate, the at least one detection unit comprising:
two metal electrodes, and
a perovskite material layer in ohmic contact with the two metal electrodes.

2. The detector according to claim 1, wherein the at least one detection unit comprises one detection unit, wherein the one detection unit comprises:
a first metal electrode of the two metal electrodes provided on the substrate;
the perovskite material layer provided on the first metal electrode; and
a second metal electrode of the two metal electrodes provided on the perovskite material layer.

3. The detector according to claim 2, wherein a size of the first metal electrode is smaller than that of the substrate; a size of the perovskite material layer is smaller than or equal to that of the first metal electrode; and a size of the second metal electrode is smaller than that of the perovskite material layer.

4. The detector according to claim 2, wherein the first metal electrode and the second metal electrode are different kinds of metal electrodes.

5. The detector according to claim 2, wherein the first metal electrode and the second metal electrode are the same kind of metal electrode.

6. The detector according to claim 1, wherein the substrate has conductivity and serves as a first metal electrode of the two metal electrodes;
the perovskite material layer is provided on the substrate; and
a second metal electrode of the two metal electrodes is provided on the perovskite material layer.

7. The detector according to claim 1, wherein the at least one detection unit comprises one detection unit, wherein the one detection unit comprises:
a perovskite material layer spin-coated on the substrate; and
the two metal electrodes provided on the perovskite material layer,
wherein a distance between the two metal electrodes is within a preset range, so as to form a channel between the two metal electrodes.

8. The detector according to claim 7, wherein a size of the perovskite material layer is smaller than or equal to that of the substrate, and a sum of sizes of the two metal electrodes is smaller than that of the perovskite material layer.

9. The detector according to claim 1, wherein a thickness of the perovskite material layer is between 100 nm and 1 μm.

10. The detector according to claim 1, wherein the at least one detection unit comprises at least two detection units, and the at least two detection units are arranged in a plane or in a line.

11. A method for preparing a wide spectrum detector, the method comprising:
preparing a first metal electrode on or as a substrate;
preparing a perovskite material layer on the first metal electrode; and
preparing a second metal electrode on a side of the perovskite material layer away from the first metal electrode.

12. The method according to claim 11, wherein before preparing a second metal electrode on a side of the perovskite material layer away from the first metal electrode, the method further comprises subjecting the first metal electrode to an ultraviolet ozone treatment, so as to improve adhesivity between the perovskite material layer and the first metal electrode.

13. The method according to claim 11, wherein preparing a perovskite material on the first metal electrode comprises using a spin-coating method or an evaporation method to prepare the perovskite material on the first metal electrode.

14. The method according to claim 11, wherein a thickness of the perovskite material layer is between 100 nm and 1 μm.

15. The method according to claim 11, wherein the first metal electrode is prepared on the substrate and wherein a size of the first metal electrode is smaller than that of the substrate; a size of the perovskite material layer is smaller than or equal to that of the first metal electrode; and a size of the second metal electrode is smaller than that of the perovskite material layer.

16. A method for preparing a wide spectrum detector, the method comprising:
preparing a perovskite material layer on a substrate; and
preparing two metal electrodes on the perovskite material layer, wherein a distance between the two metal electrodes in the horizontal direction is within a preset range.

17. The method according to claim 16, wherein a size of the perovskite material layer is smaller than or equal to that of the substrate, and a sum of sizes of the two metal electrodes is smaller than that of the perovskite material layer.

18. The method according to claim 16, wherein a thickness of the perovskite material layer is between 100 nm and 1 μm.
